(19) United States
(12) Patent Application Publication
(10) Pub. No.: US 2026/0133882 A1
(43) Pub. Date: May 14, 2026

(54) DIAGNOSABILITY FOR SHARED OUTPUT REGISTERS

(71) Applicant: International Business Machines Corporation, Armonk, NY (US)

(72) Inventors: Uma Srinivasan, Poughkeepsie, NY (US); Matthew Steven Hyde, Wappingers Falls, NY (US); Daniel Rodko, Poughkeepsie, NY (US); Thomas J. Knips, Wappingers Falls, NY (US); Alvan Wing Ng, Austin, TX (US)

(21) Appl. No.: 18/946,189

(22) Filed: Nov. 13, 2024

(51) Int. Cl. G06F 11/16

(52) U.S. Cl. CPC G06F 11/167

(57) ABSTRACT

Device, system and method for diagnosing and/or repairing memory arrays on a chip. A device includes memory arrays, where each of the memory arrays includes or is arranged with rows and columns of memory cells. A first register is shared by the memory arrays, and operable to receive failing column status data from the memory arrays and store a failing column status bit corresponding to the failing column status data. A second register is operable to receive failing memory array status data from the memory arrays, and set a failing memory array status bit corresponding to the failing memory array status data. A third register is coupled with the second register and operable to set and store an overflow status bit indicating whether more than one of the memory arrays are failing.

### BACKGROUND

The present application relates generally to computers and computer applications, and more particularly to memory array, and diagnosing and repairing chip components such as memory arrays that have shared output registers.

### BRIEF SUMMARY

The summary of the disclosure is given to aid understanding of a device, system and/or method of diagnosability for memory arrays with shared output registers, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the device, system and/or their method of operation to achieve different effects.

In some embodiments, a device is provided. The device includes memory arrays, where each of the memory arrays include rows and columns of memory cells. The device also includes a first register shared by the memory arrays. The first register is operable to receive failing column status data from the memory arrays and store a failing column status bit corresponding to the failing column status data. The device also includes a second register. The second register is operable to receive failing memory array status data from the memory arrays, and set a failing memory array status bit corresponding to the failing memory array status data. The device also includes a third register coupled with the second register. The third register is operable to set and store an overflow status bit indicating whether more than one of the memory arrays are failing or have failed.

In some embodiments, a method is provided. The method includes reading a first register that stores failing column status of memory arrays that are sharing the first register. The method also includes reading a second register that stores a status bit associated with each of the memory arrays that are sharing the first register. The method further includes reading a third register that stores an overflow status bit indicating whether more than one of the memory arrays that are sharing the first register have failing columns. The method also includes determining whether the number of bits set in the first register is equal to one. The method also includes responsive to determining that the number of bits set in the first register is equal to one, applying a repair action to a memory array corresponding to a bit that is set in the second register.

In some embodiments, a system is provided. The system includes a processor set. The system also includes memory arrays, where each of the memory arrays includes rows and columns of memory cells. The system also includes a first register shared by the memory arrays. The first register is operable to receive failing column status data from the memory arrays and store a failing column status bit corresponding to the failing column status data. The system also includes a second register operable to receive failing memory array status data from the memory arrays and set a failing memory array status bit corresponding to the failing memory array status data. The system also includes a third register coupled with the second register and operable to set and store an overflow status bit indicating whether more than one of the memory arrays are failing. The processor set is configured to read the first register that stores the failing column status of the memory arrays that are sharing the first register. The processor set is also configured to read the second register that stores the failing memory array status bit. The processor set is also configured to read the third register that stores the overflow status bit indicating whether more than one of the memory arrays that are sharing the first register have failing columns. The processor set is also configured to determine whether the number of bits set in the first register is equal to one. The processor set is also configured to, responsive to determining that the number of bits set in the first register is equal to one, apply a repair action to a memory array corresponding to a bit that is set in the second register.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 illustrates memory array failure diagnoses among multiple memory arrays in some embodiments.

FIG. 2 illustrates diagnosing failures in multiple memory arrays that share output registers in some embodiments.

FIG. 3 illustrates another example of memory array failure diagnoses in some embodiments.

FIG. 4 is a flow diagram illustrating a method of diagnosing memory array failures in some embodiments.

FIG. 5 is a flow diagram illustrating a method of performing failure diagnosis per single memory array basis in some embodiments.

FIG. 6 illustrates a circuit block diagram that implements a circuit for performing failure determination in memory arrays that share output registers, in serial manner, in some embodiments.

FIG. 7 illustrates a circuit block diagram that implements a circuit for performing failure determination in memory arrays that share output registers, in parallel manner, in some embodiments.

FIG. 8 is a diagram illustrating a hardware implementation of an overflow diagnostic logic in some embodiments.

### DETAILED DESCRIPTION

A memory array is an array of memory cells, usually a two-dimensional array of memory cells. Digital systems or devices such as computers use memory arrays to store data. A memory array is made up of rows and columns of memory cells, where each cell stores a bit of data and where a row of cells represents a word. The term memory array is also referred to interchangeably as a memory block or memory array block. Similarly, the term memory arrays are also referred to interchangeably as memory blocks or memory array blocks.

A latch in a circuit stores a single bit of data. Generally, a register is a group of latches combined to store a group of bits that make up data. Output register refers to a register that receives outputs from memory arrays or blocks. For example, output register is a group of latches that take in the expected voltages (Vs), actual (XOR) output from the memory array. They are used for diagnostic purposes. The examples described herein illustrate 6 latches for simplicity of explanation, but there may be as many as needed by the size of the memory array.

Output registers of multiple memory arrays are shared to reduce power, area, and/or other resources. Such output registers are used in diagnosing failure in memory arrays and also in providing repairs. However, because the registers are shared, shared output registers incur the cost of having to apply the same repairs to all the memory arrays or memories, even when there is a fail in one memory array among multiple memory arrays that share common output registers. In addition, discovering which one memory array has failed, may involve disabling all but one memory array at a time in order to uniquely identify the failing memory array.

By way of example, in some embodiments, a 1024 row×288 bit array could have a set of 72 bit data read out, and in this example an output register would be 72 bits wide with 1 status bit per data out). The output register is shared across many memory arrays. For example, consider that there are 32 copies of the memory array described in the example above. That would imply that the 72 bit output register is shared across all 32 memory arrays. This way, there is savings in the cost (power, area, etc.) of having 32 such output registers (each 72 bit wide), but without sacrificing the diagnosability of where the failure came from, and apply a more targeted repair.

In some embodiments, a system (e.g., a device or circuit) and method provide improved diagnosability for identifying and repairing memory arrays that share output registers. For example, with an improved diagnosability feature, repairs can be made uniquely to each memory array that is diagnosed as failing. This allows the system and method to repair only the array that needs repair and not all arrays that share an output register. Additionally, the system and method can identify a failure for each memory array by bit uniquely in debug mode. Still yet, the system and method provide an ability to repair only the circuit blocks needing repair, and not every memory array in the group of memory arrays that share the output registers.

While the methodology disclosed herein is described with respect to memory arrays for illustrating embodiments, the methodology can be applied to any other repairable circuit, including but not limited to Input/Output, logic and embedded dynamic random access memory (eDRAM).

In some embodiments, the system and method use a decoded memory block identifier associated with a group of memory arrays or blocks that share one or more output registers, that is, share the same output registers. When a group of memory blocks share output registers, the system and method add a decoded memory block identifier that indicates from which memory block the fail occurred, allowing for the ability to repair only the memory block that needs the repair. The system and method also use or add a flag that identifies whether fails are occurring from different memory blocks (in the case of multi-block fail), which will also help in cases where fails occur in more than one memory block.

Throughout the description herein, the term “failing column register” and “failing column latch” are used interchangeably; the term “decoded instance register” and “decoded instance latch” are used interchangeably. It is noted that while the description herein uses memory column fail and column repair capabilities, the system, device and method described herein can be used for detecting memory row failures and performing memory row repairs.

Table 1 shows a truth table where a failing column latch or register has 1 status bit indicating pass (0) or fail (1) for each column in the memory block. All 0's indicates no fails, any 1 indicates that the corresponding column has failed. The failing column latch represents the output register that is being shared.

TABLE 1

| | Failing | | | |
|---|---|---|---|---|
| | Column | | | |
| | (OR of | Decoded | | |
| Failing | all fail | Instance | | |
| Instance | instances) | Register | Oflow | Repair |
| 0 | 000010 | 1000 | 0 | Instance 0 |
| 1 | 100000 | 0100 | 0 | Instance 1 |
| 2 | 001000 | 0010 | 0 | Instance 2 |
| 3 | 001000 | 0001 | 0 | Instance 3 |
| 0, 1 | 001010 | 1100 | 1 | Unrepairable |
| 0, 1, 2 | 101010 | 1110 | 1 | Unrepairable |
| 0, 2 | 001010 | 1010 | 1 | Unrepairable |
| 2, 3 | 001000 | 0011 | 1 | Repairable |

By way of example, consider that there are four array blocks, referred in Table 1 as blocks 0, 1, 2, and 3. There are shared set of 6 latches that indicate the past failed status (represented by six bits shown in Failing Column in Table 1). In Row 1 of Table 1, “000010” in the Failing Column shows that memory block column five failed (since it has ‘1’ in the fifth place counting from the left). However, since there are four different memory arrays or blocks that are sharing this six column latch, it is difficult to tell which memory array or block's memory column failed. In some embodiments, decoded set of decoder latches or registers referred to as a decoded memory block identifier (referred to Table 1 as Decoded Instance Register) is added that can provide an indication of which memory array's column having failed status in the failing column latch has failed. In Row 1 of Table 1, “1000’ under Decoded Instance Register column shows that the failing memory block is memory array 0, indicated by ‘1’ in ‘1000’. For instance, each bit register in the decoded instance register indicates a status of memory block that share the same output register. In this example, since ‘1’ is set only for memory array 0, it can be understood that the only the column 5 failure occurred in memory array 0. In Table 1, Oflow (or overflow) column represents an overflow bit, which is an extra latch, which indicates whether there are more than one failure occurring in the failing column latch. In Table 1, rows 1, 2, 3 and 4 have only a single failure, as indicated by one ‘1’ set in the Failing Column, hence there are no overflows, as indicated by ‘0’s in Oflow column, it can be seen as to which memory array has failed. In these examples, all of the instances shown in rows 1, 2, 3 and 4 are repairable, as indicated by the Repair column in Table 1.

In Table 1, rows 5, 6, 7 and 8 show examples where there are multiple columns of memory arrays failing. For example, the failing column latch includes at least two bits with ‘1’s. In some embodiments, by having an added decoded set of latches (decoded instance register), it is possible to identify which memory arrays had failures. For instance, in the example shown in Table 1, row 5, the decoded instance register tells that there is a failure in memory array 0 and memory array 1 (indicated by bit settings ‘1100’). The overflow bit in this example is 1 (since there are more than a single memory array failure), and therefore it is determined to be unrepairable (as indicated in the Repair column). In row 6 of Table 1, there are three memory columns that are failing (indicated y ‘101010’ in Failing Column) and three memory arrays that are failing (indicated by ‘1110’ in Decoded Instance Register). In this example, overflow bit is 1 (since there are more than a single memory array failure), and therefore it is determined to be unrepairable (as indicated in the Repair column). In row 7 of Table 1, the decoded instance register tells that there is a failure in memory array 0 and memory array 2 (indicated by bit settings ‘1010’). Failing Column in row 7 of Table 1 shows ‘001010’ indicating that columns 3 and 5 of some memory arrays failed. In this example, overflow bit is 1 (since there are more than a single memory array failure). Since it is not yet determined which memory array's which memory column failed, Repair column is set as unrepairable, similarly to rows 5 and 6 in Table 1. That is, in the examples shown in rows 5, 6 and 7, while it can be diagnosed that which two different memory arrays have failed, and which memory columns have failed, as to which memory array's which column has failed in not identifiable.

In row 8 of Table 1, Failing Column shows a single ‘1’ in ‘001000’, indicating that a third memory column of some memory array has failed. In this example, the decoded latch (Decoded Instance Register) shows that two memory arrays failed (indicated by status ‘0011’), i.e., memory arrays 2 and 3 have failed status set. In this example, the same memory column failed in both memory arrays 2 and 3. In this case, no further debug is needed since both memory arrays are identified as having failed and can be repaired, e.g., as indicated by Repair column.

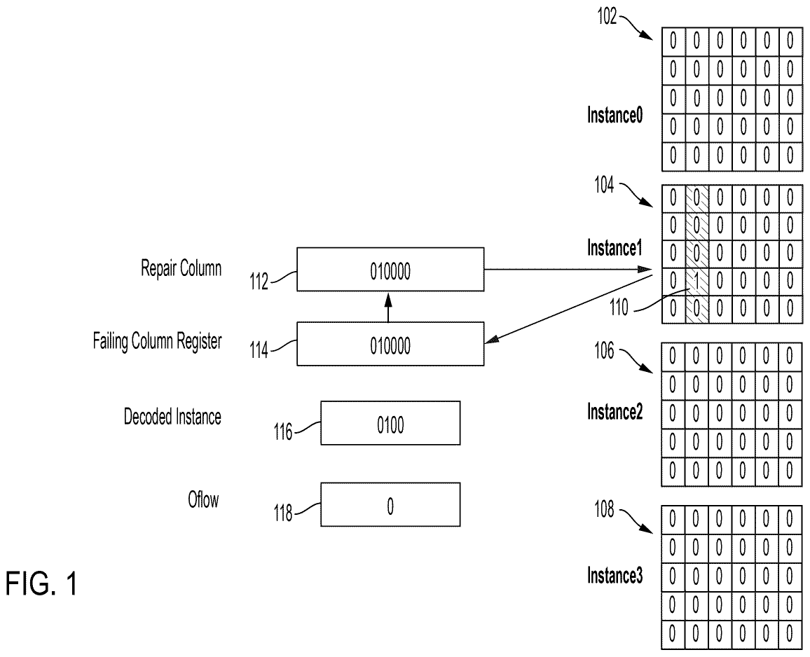

FIG. 1 illustrates a memory array failure diagnoses among multiple memory arrays in some embodiments. By way of example, simple 6×6 memory arrays 102, 104. 106, 108 with compressed bits are shown, e.g., memory array 0 (shown as Instance0) 102, memory array 1 (shown as Instance1) 104, memory array 2 (shown as Instance2) 106, and memory array 3 (shown as Instance3) 108. The memory arrays 102, 104. 106, 108 are sharing output registers. The example shown indicates that only memory array 1 (shown as Instance1) 104 failed, which shows ‘1’ in its second column at fourth row 110. Even if there is one bit failing in a given column, a repair column 112 is set, and the status bit for this column gets set to one in a failing column register 114, as shown as ‘010000’. In decoded instance register 116, status bit for only Instance1 is set to one, for example, ‘0100’. Overflow bit or register 118 is set to ‘0’ because there is only a single failing column. Since it can be seen that the decoded instance is Instance1 and there is only a single failure, repair action can be performed on Instance1. In sum, FIG. 1 shows an example where only one memory array (e.g., Instance1) failed. It is considered to be repairable, since only a single ‘1’ is set in the failing column latch or register 114 (e.g., one column per instance is repairable) and a repair action is sent only to this memory array (e.g., Instance1).

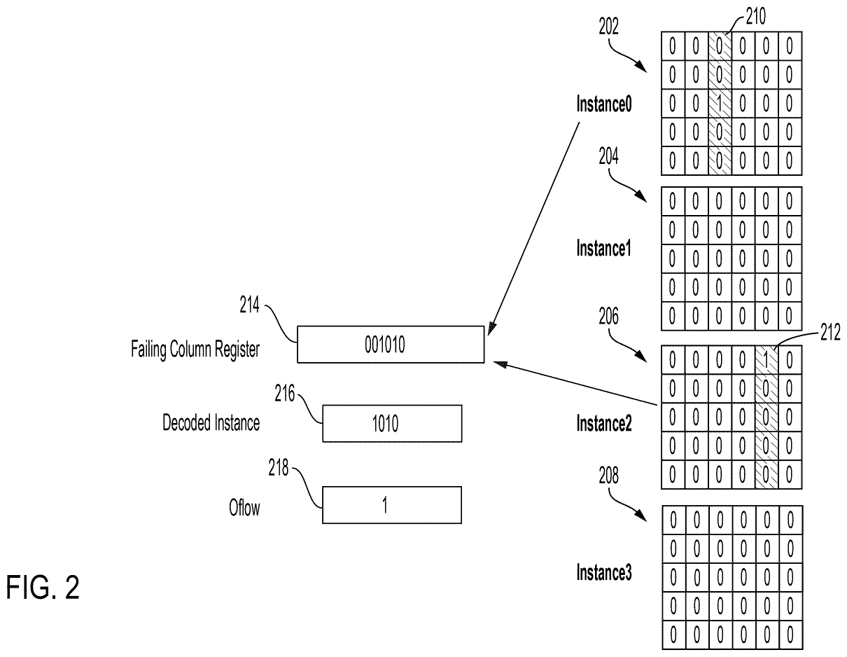

FIG. 2 illustrates diagnosing failures in multiple memory arrays that share output registers in some embodiments. Consider by way of example, that there are four memory arrays 202, 204, 206, 208, sharing output registers. This example shows that memory array 0 (Instance0) 202 and memory array 2 (Instance2) 206 failed. In this example, additional investigation or debugging may be needed before a repair, since two different columns are failing across two instances (only one column per instance is repairable, as in this example, memory arrays that allow only 1 column repair is being used. This method can also be used for other memory arrays that allow any number of columns or rows to be repaired). Here, the third column 210 of Instance0 202 has some fail as shown by the ‘1’ set at column 210 in its third row. The failing column register 214 shows this failure by setting the third bit (counting from the left) to ‘1’. This indicates that there is some fail in a third column of a memory array. Decoded instance register 216 has ‘1’ set in the first bit position (counting from the left) to indicate that it is memory array 0 (Instance0) that has a failure.

Also in this example, memory array 2 (Instance2) 206 has a fail in its fifth column 212 (as shown by ‘1’ set in its first row of fifth column). To indicate this failure status, the failing column register 214 has ‘1’ set in its fifth position (counting from the left). Hence, the failing column register 214 is set as ‘001010’ to indicate failure status in third and fifth columns of memory arrays. Decoded instance register 216 also has its third position (counting from the left) set to ‘1’ to indicate that memory array 2 (Instance2) 206 has failing column. Hence, decoded instance register 216 is set as ‘1010’ to indicate that memory array 0 and memory array 2 have failing columns. Overflow bit in oflow (overflow register) 218 is set to ‘1’ because there are more than a single memory array that has a failing column. In this example, further analysis or debugging should be done to determine which failed column corresponds with which memory array. For instance, reading these two registers (failing column register 214 and decoded instance register 216) alone does not inform where the failure is occurring, that is, which failing column (third column or fifth column) corresponds to which memory array (Instance0 or Instance2) instance. Hence, further analysis should be performed to locate where the failure is occurring before performing a repair.

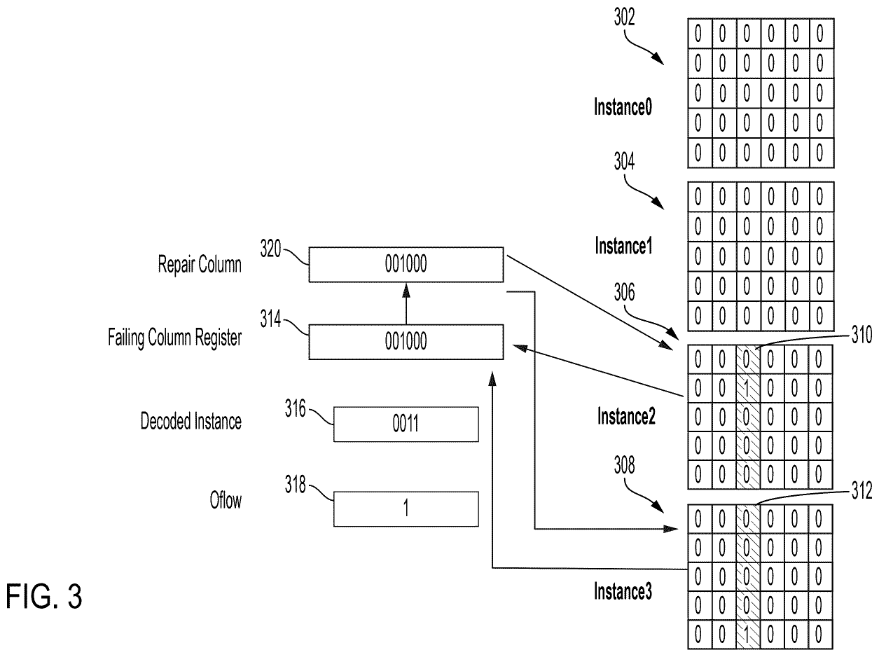

FIG. 3 illustrates another example of memory array failure diagnoses in some embodiments. Thise example indicates that memory array 2 (Instance2) 306 and memory array 3 (Instance3) 308 failed. It is repairable, since the same column (310, 312 which are both third columns in Instance2 306 and Instance3 308) is failing across two instances, as shown by failing column register 314 and decoded instance latch or register 316. Repair action can be sent to Instance2 306 and instance3 308 via a repair column register 320.

In more detail, by way of example only, consider there are four memory arrays 302, 304, 306, 308 sharing output registers. Here, both Instance2 306 and instance3 308 happened to fail on the same column (third column 310, 312). The failing column register 314 has third bit (counting from the left) set to ‘1’, as shown (‘001000’), indicating a failure in a third column of some memory array or arrays. Decoded instance 316 has both third and fourth status bit set to ‘1’ (as shown by ‘0011’, again counting from the left) to indicate that both Instance2 306 and Instance3 308 failed. Since there are more than one memory array failure happening, the overflow bit of oflow (overflow register) 318 is set to ‘1’. In this example, a repair can be made without further analysis since it can be seen which memory array has which column that failed. That is, reading the failing column register 314 and decoded instance register 316 shows that both memory arrays 306, 308 have their third columns failing. Since this example presents a repairable scenario, repair column register 320 is set to have its third column (counting from the left, as shown by ‘001000’), and repair action is applied via the repair column 320 to both memory arrays, Instance2 306 and Instance3 308. In this example, even if the overflow bit is set to ‘1’ at 318, the failing memory arrays can be repaired.

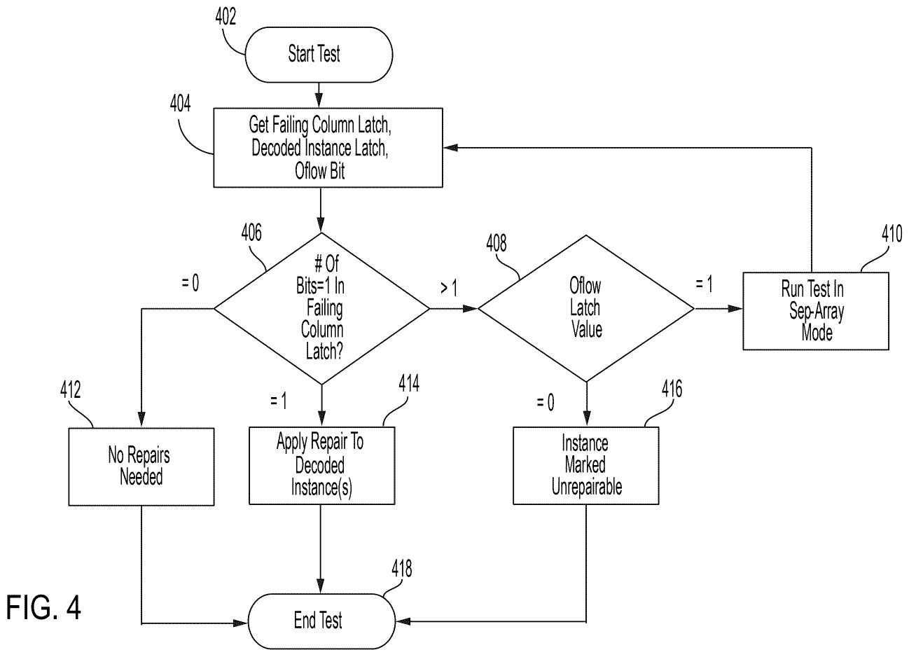

FIG. 4 is a flow diagram illustrating a method of diagnosing memory array failures in some embodiments. At 402 testing starts. For instance, testing can take place in manufacturing facilities of semiconductions and circuit boards or chips having memory arrays or blocks, and for example, during manufacturing stage. At 404, registers including failing column latch, decoded instance latch, and overflow bit are read. Failing column latch or register, decoded instance latch or register and overflow register (oflow) are described above with references to FIGS. 1-3.

At 406, number of bits that are set (e.g., set to value of ‘1’) in the failing column latch or register is determined and if the number of bits set to ‘1’ is determined to be zero, at 412, it is determined that no repairs are needed and at 416 the test ends. If at 406, it is determined that the number of bits set to ‘1’ is equal to one, at 414, repair is applied to one or more memory arrays indicated in the decoded instance register (e.g., determined by the status bit positions in the decoded instance register), and at 416, the test ends.

If at 406, it is determined that the number of bits set to ‘1’ is greater than one, at 408, the overflow bit is checked. If at 408, it is determined that the overflow bit (in overflow latch) is zero, at 416, memory arrays are marked or tagged as unrepairable, since a repair is done per column per memory array, and in this example scenario, there are multiple column failures in one memory array.

If at 408, it is determined that the overflow bit (in overflow latch) is set (e.g., to ‘1’), at 410, further test (e.g., further debugging or analysis) is performed as a single memory array basis, e.g., in separate memory array mode, since it cannot be determined only by reading the failing column latch and the decoded instance latch, which column of which memory array has failed. This separate test mode can be done in debug mode, and not necessarily in manufacturing mode, for example, in determining which memory arrays or blocks are failing and which bits are failing in those memory arrays or blocks.

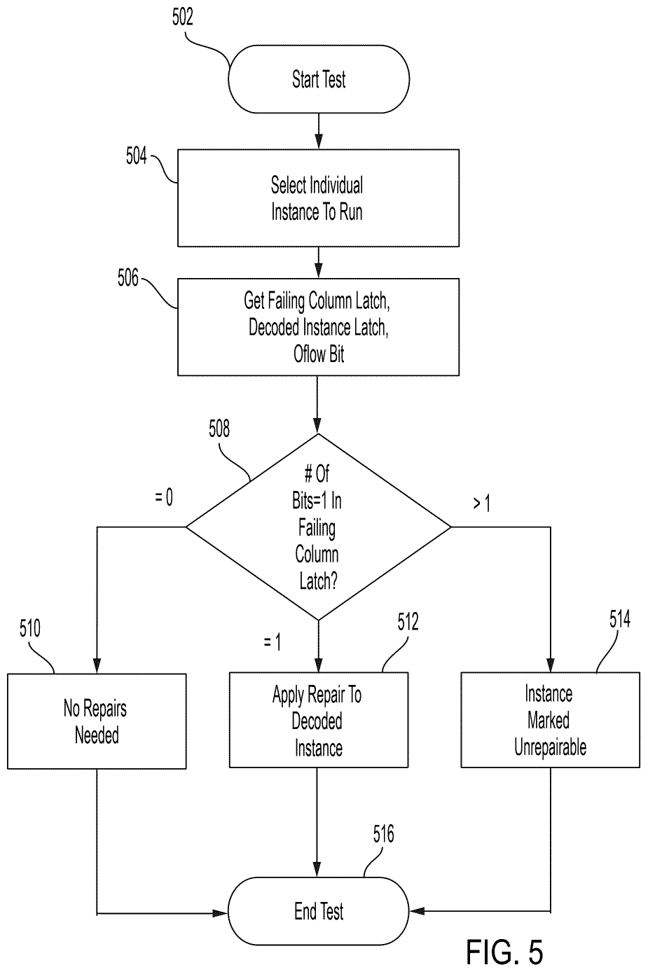

FIG. 5 is a flow diagram illustrating a method of performing failure diagnosis per single memory array basis in some embodiments. This method can be used, for example, in 410 in FIG. 4, to perform further debugging and/or analysis that determines which failing column corresponds to which memory array that has its status bit set in the decoded instance latch or register. At 510, a test to diagnose a memory array starts. At 504, a memory array to diagnose is selected, e.g., individual instance of a memory array is selected to run. At 506, registers including failing column latch, decoded instance latch, and overflow bit are read. At 508, the number of bits that are set (e.g., set to value of ‘1’) in the failing column latch or register is determined.

If at 508, the number of bits set to ‘1’ is zero, at 510, it is determined that no repairs are needed and at 516 the test ends. If at 508, the number of bits set to ‘1’ is one, at 512, repair is applied to the memory array (selected for this run) and indicated in the decoded instance register (e.g., determined by the status bit positions in the decoded instance register), and at 516, the test ends.

If at 508, it is determined that the number of bits set to ‘1’ is greater than one, at 514, this memory array is marked as unrepairable since there are more than one columns failing in a single memory array, and since only one column repair is applied to a memory array.

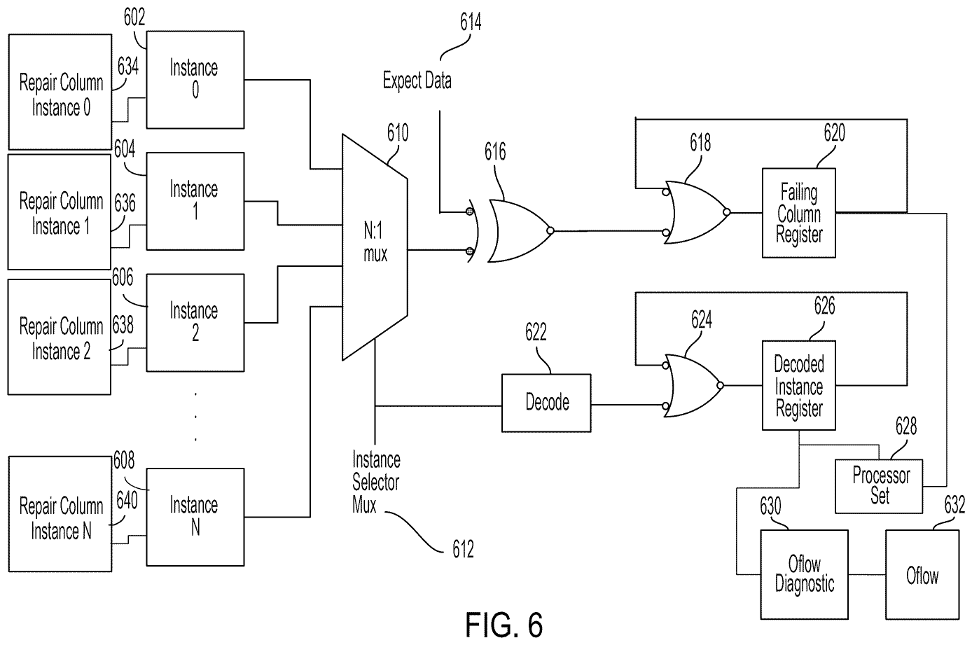

FIG. 6 illustrates a circuit block diagram that implements a circuit for performing failure determination in memory arrays that share output registers, in serial manner, in some embodiments. There can be multiple memory arrays (e.g., Instance 0, Instance 1, Instance 2, . . . , Instance N, where N is an integer). In this example, there are N+1 memory arrays (from 0 to N). The memory arrays 602, 604, 606, 608 are connected to N:1 mux (N to 1 multiplexer) 610. Memory arrays [0:N] 602, 604, 606, 608 (also referred to as Instances [0:N]) are run in serial mode through the N:1 mux 610 determined by an instance selector multiplexer (mux) 612. That is, all memory array [0:N] 602, 604, 606, 608 sends or output data to N:1 mux 610 and an ability to run in a serial mode is implemented by having an instance selector mux 612 select a single memory array that is a target for testing or to test. There is an expect data 614, which is XOR′ed (logical Exclusive OR function) by XOR gate 616. N:1 mux 610 and expect data 614 line are connected to an XOR gate 616. Expect data 614 is compared with only the output of the memory array that is selected by instance selector mux 612 at the XOR gate 616. The XOR gate 616 is connected to an OR gate 618. The OR gate 618 is connected to a failing column register 620. The output from XOR gate 616 is sent to an OR gate 618, where it is combined with any previous content of the failing column register 620. Decoder 622 is connected with the instance selector mux 612, and provides information as to which memory array is being targeted for testing, as selected by the instance selector mux 612. The decoder 622 is connected further with an OR gate 624. OR gate 624 is connected to decoded instance register 626. The decoded instance register 622 stores status bits corresponding to memory arrays 602, 604, 606, 608. Output from the decoder 622 (indicating which memory array is targeted for testing) is sent to the OR gate 624, where it is combined with any previous content of the decoded instance register 626. In this way, status bit corresponding to the selected memory array for testing as selected by the instance selector mux 612 is set in the decoded instance register 626.

In some embodiments, failing columns are stored in a sticky accumulate failing column latch or register 620. In some embodiments, the same structure is used to store the decoded instance information in the decoded instance register 626. In this serial mode or separate array test, instance selector mux 612 can act as a counter that cycles through in selecting each of the memory arrays 602, 604, 606, 608 separately in a serial manner for testing.

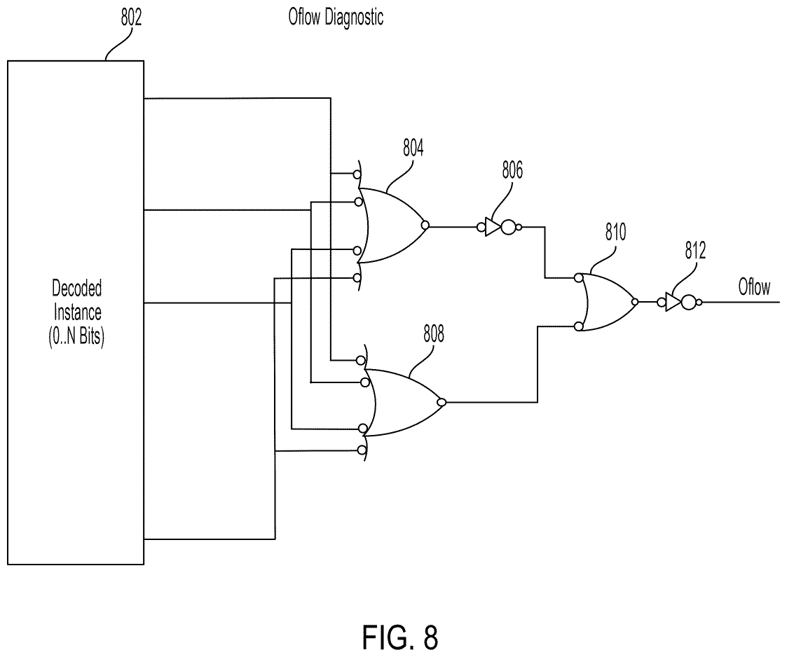

In some embodiments, a processor set 628 reads the registers, e.g., failing column register 620, decoded instance register 626 and performs test methods, e.g., described above with reference to FIGS. 4 and/or 5. Repair column instances 0-N shown at 634, 636, 638 and 640 include a corresponding bit set for that memory array (602, 604, 606, 608), responsive to determining that the corresponding memory array has failed and can be repaired (e.g., as also shown in FIG. 1 and FIG. 3). In some embodiments, repair column instance 0, 1, 2 . . . N shown at 634, 636, 638 and 640 have unique contents corresponding to each memory array instance 0, 1, 2 . . . N shown at 602, 604, 606, 608. Overflow diagnostic 630 logic (e.g., hardware logic shown in FIG. 8), based on decoded instance register 626, outputs whether there is an overflow or not, that is, whether there are multiple memory arrays failing or a single memory array failing. Overflow register 632 receives that output and stores it. In some embodiments overflow diagnostic 630 logic can be implemented using software.

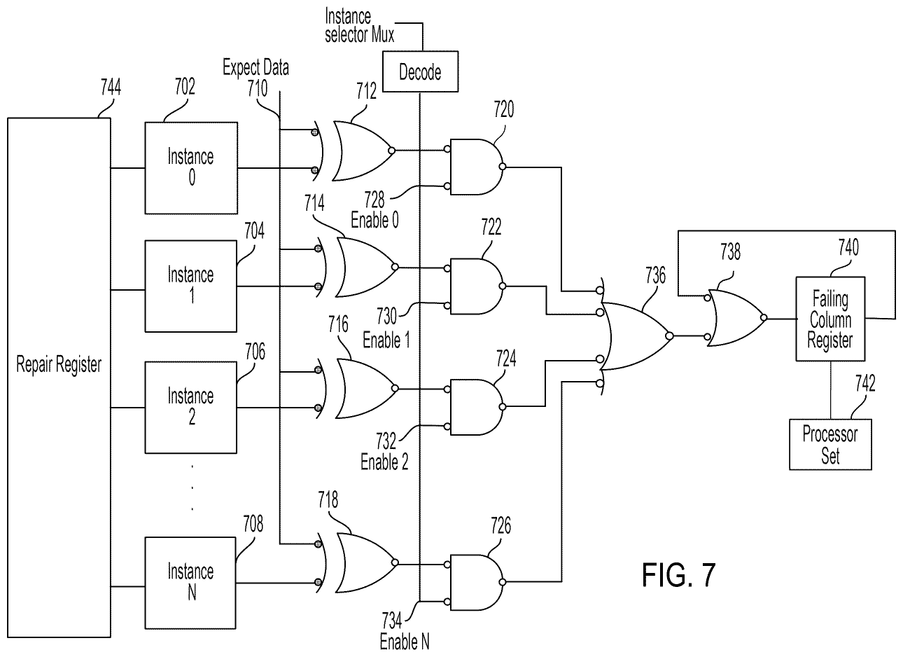

FIG. 7 illustrates a circuit block diagram that implements a circuit for performing failure determination in memory arrays that share output registers, in parallel manner, in some embodiments. Similar to the example shown in FIG. 6, there can be multiple memory arrays (e.g., Instance 0, Instance 1, Instance 2, . . . , Instance N, where Nis an integer). In this example, there are N+1 memory arrays (from 0 to N). The memory arrays 702, 704, 706, 708 are connected, each to a respective XOR gate 712, 714, 716, 718. Expect data line 710 is also connected to the XOR gates 712, 714, 716, 718. Each XOR gate 712, 714, 716, 718 receives output from the respective memory arrays 702, 704, 706, 708 and the expect data line 710, where the data is XOR′ed. XOR gates 712, 714, 716, 718 are connected to respective AND gates 720, 722, 724, 726. Each of the AND gates 720, 722, 724, 726 also has an Enable line 728, 730, 732, 734 for input. Respective output from the XOR gates 712, 714, 716, 718 and corresponding Enable line bit is input or fed to the respective AND gates 720, 722, 24, 726. All of the AND gates 720, 722, 24, 726 are connected to an OR gate 736. Outputs from the AND gates 720, 722, 24, 726 are input to the OR gate 736. The output from the OR gate 736 is fed into another OR gate 738 (that is connected with the OR gate 736) and OR′ed with any previous content of a failing column register 740. Output from the OR gate 738 is fed into the failing column register 740, which stores status bits of failing columns. This failing column register 740 stores status for any column fail from any of the memory arrays 702, 704, 706. 708, and all of the failing column information is stored in a single set of failed column register 740. In this parallel scenario, even though the same failed column register is used as in the serial testing mode shown in FIG. 6, status bits for failing columns from all memory arrays are compressed or OR′ed and stored into a single register. The circuit implementation shown in FIG. 7 allows for running or testing memory arrays in parallel. Repairs are shared among memory arrays. Generally, all the Enable lines 728, 730, 832, 734 are enabled at the same time. In some scenarios, the exact failing instance is not known in this implementation. Separate array mode can be implemented optionally by toggling the Enable line (e.g., one of 728, 730, 732, 734) that corresponds to the memory array desired for testing, e.g., sequencing the Enable lines. Any combinations of one or more memory arrays can be grouped for testing.

In some embodiments, enable bit of the Enable lines 728 can be turned on for a group of memory arrays, that is, fewer than all of the Enable lines. This way, a select number of memory arrays can be tested together. In some embodiments, skip counters such as skip-two-counter (counter that jumps two counts), skip-four-counter (counter that jumps four counts), etc., can be used to implement testing a select group of memory arrays in serial test mode. This way, error prone memory arrays or memory arrays located in areas on the chip or circuit board prone to fail, can be isolated and tested, without having to test all memory arrays that share a single output register.

In some embodiments, a processor set 742 reads the output register, e.g., failing column register, and performs test methods, e.g., described above with reference to FIGS. 4 and/or 5. A repair register 744 that is common to all memory arrays 702, 704, 706, 708 is coupled to or connected to the memory arrays 702, 704, 706, 708, that communicate which memory arrays are to be repaired.

FIG. 8 illustrates and example implementation of a hardware overflow diagnostic logic in some embodiments. Decoded instance register 802 is connected to (or coupled with) an OR gate 804 and an XOR gate 808. The OR gate 804 is connected to (or coupled with) a NOT gate 806. The NOT gate 806 is connected to (or coupled with) an OR gate 810. The XOR gate 808 is also connected to (or coupled with) the OR gate 810. The OR gate 810 is connected to (or coupled with) a NOT gate 812. As described above, decoded instance register 802 stores N bits, where each bit corresponds to a status of a memory array among the memory arrays sharing an output register (e.g., described above as a failing column register). Content of decoded instance register 802 (e.g., bits stored) are input to OR gate 804 and also to XOR gate 808. At 804, all the bits of decoded instance register 802 are logically OR′ed and the output of that OR operation is input to NOT gate 806. Also at 808, all the bits of decoded instance register 802 are logically XOR′ed. Outputs from NOT gate 806 and XOR gate 808 are input to OR gate 810. Output from OR gate 810 is input to NOT gate 812. Output of NOT gate 812 is a bit indicating whether or not there is an overflow. That output is stored in an overflow register.

In some embodiments, depending on the desired cost savings, e.g., reducing test times or duration, parallel or serial test mode can be chosen, e.g., parallel test mode can be chosen over the serial test mode, since testing all of the memory arrays at the same time would take less time than testing the memory arrays one at a time via the serial test mode. On the other hand, a serial test mode can identify from which memory array or arrays, one or more column failures occurred.

In some embodiments, an output register (referred to above as failing column register) receives fail data from a multiplexer of multiple memory arrays or blocks. An associated diagnostic register (referred to above as decoded instance register) is provided that contains status data as to which one or more memory arrays failed. An associated overflow register is provided to indicate an overflow condition, where the overflow condition represents that there are fails across multiple memory arrays. An overflow register can be useful in determining whether there is an isolated failure in one memory block, or whether there are failures occurring across multiple memory blocks. An option is provided to run in a test mode where each individual memory arrays are tested separately, to check repairability of each memory array instance.

System and method described herein allow for reducing the number of latches needed for adding repairability to circuits on a chip (also providing space savings on the chip), at the same time, without sacrificing diagnosability. The system and method also provide the ability to repair only the circuit blocks that need repair (referred to as targeted repairability), and not every memory array or block in the group of memory arrays or blocks that share the output register.

While the illustrations described and shown herein refer to four memory arrays sharing an output register, there can be many more memory arrays that share the same output register. For example, 16 memory arrays (or another multiple number) may share a single output register. By way of example, the width of a failing column register may be 32 or 48 (or another width). By sharing a failing column register, and having an additional decoded instance register with width equal to the number of memory arrays, savings of space and number of latches is: (failing column register width*number of memory arrays)−(failing column register width+number of memory arrays).

As described and illustrated above, in some embodiment, a device is provided that includes memory arrays, where each of the memory arrays has rows and columns of memory cells, for example, as shown in FIGS. 1-3. Memory arrays are also shown in FIGS. 6-7. A first register (also referred to above as a failing column register) is shared by the memory arrays, and is operable to receive failing column status data from the memory arrays and store a failing column status bit corresponding to the failing column status data. Failing column status data refers to data that indicates which column of a memory array has failed. Failing column status bit refers to a bit that is set or reset in the first register, for example, as described above with reference to a failing column register. A second register (also referred to above as a decoded instance register) is operable to receive failing memory array status data from the memory arrays, and set a failing memory array status bit corresponding to the failing memory array status data. Failing memory array status data refers to data the indicates status of a memory array, whether or not the memory array has a failing column, for example, as described above with reference to a decoded instance register. Failing memory array status bit refers to a bit that is set or reset in the second register, for example, as described above with reference to a decoded instance register. A third register (also referred to as an oflow or overflow register) is coupled with the second register and operable to set and store an overflow status bit indicating whether more than one of the memory arrays are failing and/or have failed.

In some embodiment, the device also includes a multiplexer connected to the memory arrays for selecting a memory array among the memory arrays, where the failing column status data from the selected memory array is received in the second register. An example of this configuration is illustrated in FIG. 6. In some embodiment, the failing column status data from each of the memory arrays is input to a respective AND gate with an enable bit, wherein output from each of the respective AND gate are input to an OR gate, and the first register receives output of the OR gate. An example of this configuration is shown in FIG. 7. In some embodiments, the enable bit is set for a subset of the memory arrays, for selecting a group of memory arrays.

In some embodiments, the memory arrays have N columns of memory cells, and the first register has a bit width of at least N, where N is an integer. In some embodiments, the second register has a bit width of at least a number of the memory arrays that are sharing the first register. For example, for a K number of memory arrays sharing an output register, the width of the first register is K (or K bits). K is an integer. In some embodiments, the third register is a latch having a capacity to store one bit of data, for example, an overflow status bit.

In some embodiments, the memory arrays have N columns of memory cells, and the first register has a bit width of at least N, where each bit position in the first register stores a status bit associated with one of the N columns, where each of the N columns is represented in the first register.

In some embodiments, the second register has a bit width of at least a number of the memory arrays that are sharing the first register, where each bit position in the second register stores a status bit associated with one of the memory arrays, where each of the memory arrays is represented in the second register.

As described and illustrated above, one or more methods are provided that can diagnose and/or repair one or more memory arrays, for example, which are being fabricated on a chip or circuit board, for example, as shown in FIGS. 4 and/or 5. A method includes reading a first register (also referred to above as a failing column register) that stores failing column status of memory arrays that are sharing the first register. The method also includes reading a second register (also referred to above as a decoded instance register) that stores a status bit associated with each of the memory arrays that are sharing the first register. The method also include reading a third register (also referred to above as an overflow register) that stores an overflow status bit indicating whether more than one of the memory arrays that are sharing the first register have failing columns. The method also includes determining whether the number of bits set in the first register is equal to one. The method also includes, responsive to determining that the number of bits set in the first register is equal to one, applying a repair action to a memory array corresponding to a bit that is set in the second register. In this way, for example, repair can be made selectively only to one or more memory arrays that are failing (e.g., have failed), and not all memory arrays that share an output register (e.g., failing column register).

In some embodiments, the method also includes determining whether the number of bits set in the first register is greater than one. The method also includes, responsive to determining that the number of bits set in the first register is greater than one, determining whether the third register has the overflow status bit set indicating more than one of the memory arrays that are sharing the first register have failing columns (e.g., have failed columns). The method also includes, responsive to determining that overflow status bit is set indicating more than one of the memory arrays that are sharing the first register have failing columns, testing each of the memory arrays separately in a serial manner.

In some embodiments, responsive to determining that overflow status bit is not set, the method also includes marking as unrepairable, the memory array corresponding to the bit that is set in the first register. In some embodiments, the testing each of the memory arrays separately includes receiving and storing in the first register the failing column status of columns associated with one memory array at a time.

In some embodiments, a system is provided that performs the methods described above. In some embodiments, the system includes a processor set, which is configured to perform the methods described here. A processor set includes one, or more, computer processors of any type now known or to be developed in the future. A processor set can include processing circuitry, which may be distributed over multiple packages, for example, multiple, coordinated integrated circuit chips. Processing circuitry may implement multiple processor threads and/or multiple processor cores. A processor set can also include cache, memory that is located in the processor chip package(s) and is typically used for data or code that should be available for rapid access by the threads or cores running on the processor set. Cache memories are typically organized into multiple levels depending upon relative proximity to the processing circuitry. Alternatively, some, or all, of the cache for the processor set may be located “off chip.” In some embodiments, the processor set is configured to, or caused to, perform the methods described herein for diagnosing and/or repairing memory arrays on a chip.

For example, a system includes a processor set. The system also includes memory arrays, each of the memory arrays comprising rows and columns of memory cells. The system also includes a first register shared by the memory arrays, and operable to receive failing column status data from the memory arrays and store a failing column status bit corresponding to the failing column status data. The system also includes a second register operable to receive failing memory array status data from the memory arrays, and set a failing memory array status bit corresponding to the failing memory array status data. The system also includes a third register coupled with the second register and operable to set and store an overflow status bit indicating whether more than one of the memory arrays are failing.

In some embodiments, the processor set is configured to, or caused to, read the first register that stores the failing column status of the memory arrays that are sharing the first register, read the second register that stores the failing memory array status bit, read the third register that stores the overflow status bit indicating whether more than one of the memory arrays that are sharing the first register have failing columns. The processor set is also configured to, or caused to, determine whether the number of bits set in the first register is equal to one. Responsive to determining that the number of bits set in the first register is equal to one, the processor set is also configured to, or caused to, apply a repair action to a memory array corresponding to a bit that is set in the second register.

In some embodiments, the processor set is further configured to, or caused to, determine whether the number of bits set in the first register is greater than one. Responsive to determining that the number of bits set in the first register is greater than one, the processor set is also configured to, or caused to, determine whether the third register has the overflow status bit set indicating more than one of the memory arrays that are sharing the first register have failing columns. Responsive to determining that overflow status bit is set indicating more than one of the memory arrays that are sharing the first register have failing columns, the processor set is also configured to, or caused to, test each of the memory arrays separately in a serial manner.

In some embodiments, responsive to determining that the overflow status bit is not set, the processor set is further configured to, or caused to, mark as unrepairable, the memory array corresponding to the bit that is set in the first register.

In some embodiments, the processor set is configured to, or caused to, test each of the memory arrays separately by at least receiving and storing in the first register the failing column status of columns associated with one memory array at a time.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in some embodiments” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A device, comprising:
memory arrays, each of the memory arrays comprising rows and columns of memory cells;
a first register shared by the memory arrays, and operable to receive failing column status data from the memory arrays and store a failing column status bit corresponding to the failing column status data;
a second register operable to receive failing memory array status data from the memory arrays, and set a failing memory array status bit corresponding to the failing memory array status data; and
a third register coupled with the second register and operable to set and store an overflow status bit indicating whether more than one of the memory arrays are failing.

2. The device of claim 1, further including a multiplexer connected to the memory arrays for selecting a memory array among the memory arrays, wherein the failing column status data from the selected memory array is received in the second register.

3. The device of claim 1, wherein the failing column status data from each of the memory arrays is input to a respective AND gate with an enable bit, wherein output from each of the respective AND gate are input to an OR gate, and the first register receives output of the OR gate.

4. The device of claim 3, wherein the enable bit is set for a subset of the memory arrays, for selecting a group of memory arrays.

5. The device of claim 1, wherein the memory arrays have N columns of memory cells, and the first register has a bit width of at least N.

6. The device of claim 1, wherein the second register has a bit width of at least a number of the memory arrays that are sharing the first register.

7. The device of claim 1, wherein the third register is a latch having a capacity to store one bit of data.

8. The device of claim 1, wherein the memory arrays have N columns of memory cells, and the first register has a bit width of at least N, wherein each bit position in the first register stores a status bit associated with one of the N columns, wherein each of the N columns is represented in the first register.

9. The device of claim 1, wherein the second register has a bit width of at least a number of the memory arrays that are sharing the first register, wherein each bit position in the second register stores a status bit associated with one of the memory arrays, wherein each of the memory arrays is represented in the second register.

10. A method comprising:
reading a first register that stores failing column status of memory arrays that are sharing the first register;
reading a second register that stores a status bit associated with each of the memory arrays that are sharing the first register;
reading a third register that stores an overflow status bit indicating whether more than one of the memory arrays that are sharing the first register have failing columns;
determining whether the number of bits set in the first register is equal to one;
responsive to determining that the number of bits set in the first register is equal to one, applying a repair action to a memory array corresponding to a bit that is set in the second register.

11. The method of claim 10, further comprising:
determining whether the number of bits set in the first register is greater than one;
responsive to determining that the number of bits set in the first register is greater than one, determining whether the third register has the overflow status bit set indicating more than one of the memory arrays that are sharing the first register have failing columns;
responsive to determining that overflow status bit is set indicating more than one of the memory arrays that are sharing the first register have failing columns, testing each of the memory arrays separately in a serial manner.

12. The method of claim 11, wherein responsive to determining that overflow status bit is not set, marking as unrepairable, the memory array corresponding to the bit that is set in the first register.

13. The method of claim 11, wherein the testing each of the memory arrays separately includes receiving and storing in the first register the failing column status of columns associated with one memory array at a time.

14. A system comprising:
a processor set;
memory arrays, each of the memory arrays comprising rows and columns of memory cells;
a first register shared by the memory arrays, and operable to receive failing column status data from the memory arrays and store a failing column status bit corresponding to the failing column status data;
a second register operable to receive failing memory array status data from the memory arrays, and set a failing memory array status bit corresponding to the failing memory array status data; and
a third register coupled with the second register and operable to set and store an overflow status bit indicating whether more than one of the memory arrays are failing;
the processor set configured to:
read the first register that stores the failing column status of the memory arrays that are sharing the first register;
read the second register that stores the failing memory array status bit;
read the third register that stores the overflow status bit indicating whether more than one of the memory arrays that are sharing the first register have failing columns;
determine whether the number of bits set in the first register is equal to one;
responsive to determining that the number of bits set in the first register is equal to one, apply a repair action to a memory array corresponding to a bit that is set in the second register.

15. The system of claim 14, wherein the processor set is further configured to:
determine whether the number of bits set in the first register is greater than one;
responsive to determining that the number of bits set in the first register is greater than one, determine whether the third register has the overflow status bit set indicating more than one of the memory arrays that are sharing the first register have failing columns;
responsive to determining that overflow status bit is set indicating more than one of the memory arrays that are sharing the first register have failing columns, test each of the memory arrays separately in a serial manner.

16. The system of claim 15, wherein responsive to determining that the overflow status bit is not set, the processor set is further configured to mark as unrepairable, the memory array corresponding to the bit that is set in the first register.

17. The system of claim 15, wherein the processor set is configured to test each of the memory arrays separately by at least receiving and storing in the first register the failing column status of columns associated with one memory array at a time.

18. The system of claim 14, further including a multiplexer connected to the memory arrays for selecting a memory array among the memory arrays, wherein the failing column status data from the selected memory array is received in the second register.

19. The system of claim 14, wherein the failing column status data from each of the memory arrays is input to a respective AND gate with an enable bit, wherein output from each of the respective AND gate are input to an OR gate, and the first register receives output of the OR gate.

20. The system of claim 19, wherein the enable bit is set for a subset of the memory arrays, for selecting a group of memory arrays.
